(19) United States
(12) Patent Application Publication
(10) Pub. No.: US 2004/0214422 A1
(43) Pub. Date: Oct. 28, 2004

(54) Semiconductor devices, and manufacturing methods, circuit substrates and electronic equipments for the same

(75) Inventor: Akira Sato, Sakata-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/625,689

(22) Filed: Jul. 24, 2003

(30) Foreign Application Priority Data
Jul. 25, 2002 (JP) 2002-216659

(51) Int. Cl. H01L 21/4763

(52) U.S. Cl. 438/622

(57) ABSTRACT

The invention provides semiconductor devices that are excellent in mountability. The invention also provides manufacturing methods, circuit substrates and electronic equipments for the same. A method of manufacturing a semiconductor device includes lowering the height of at least one of a plurality of external terminals that are electrically connected to a semiconductor chip mounted on one surface of a substrate and sealed with resin, and that are provided on another surface of the substrate in plural rows and plural columns.

### BACKGROUND OF THE INVENTION

1. Field of Invention

The present invention relates to semiconductor devices. The present invention also relates to manufacturing methods, circuit substrates and electronic equipments for the same.

2. Description of Related Art

In the related art, in area array packages, semiconductor chips can be molded and sealed therein.

However, when the semiconductor chips are molded and sealed, there are occasions where the substrate may warp due to shrinkage of the molding resin upon its hardening. In this case, there are occasions where tips of the external terminals may not be disposed on the same plane, and the semiconductor devices cannot be mounted on the mounting substrate. Also, when external terminals are too large, the assembly height of semiconductor device may become too high, such that there are cases where the semiconductor device cannot be mounted on the mounting substrate.

### SUMMARY OF THE INVENTION

The present invention addresses or solves the above and/or other problems, and provides semiconductor devices that are excellent in mountability. The invention also provides manufacturing methods, circuit substrates and electronic equipments for the same.

A method of manufacturing a semiconductor device in accordance with the present invention includes lowering the height of at least one of a plurality of external terminals that are electrically connected to a semiconductor chip mounted on one surface of a substrate and sealed with resin, and that are provided on another surface of the substrate in plural rows and plural columns.

In accordance with the present invention, since the height of the external terminals is lowered, a semiconductor device that is excellent in mountability can be manufactured.

In the method of manufacturing a semiconductor device, a tip of the at least one of the external terminals may be grounded to lower the height.

By this method, a semiconductor device that is excellent in mountability can be readily manufactured.

In the method of manufacturing a semiconductor device, the height of the at least one of the external terminals may be lowered such that tips of the plurality of external terminals are disposed on generally the same plane.

The method of manufacturing a semiconductor device may further include warping the substrate toward the side of a surface thereof on which the semiconductor chip is mounted.

The method of manufacturing a semiconductor device may further include warping the substrate toward the side of a surface thereof on which the external terminals are formed.

In the method of manufacturing a semiconductor, the external terminals may be disposed in an area array configuration.

In the method of manufacturing a semiconductor device, after forming the plurality of external terminals to the same height, the height of at least one of the external terminals may be lowered.

By this method, since the external terminals having the same size can be used, the semiconductor device can be readily manufactured.

In the method of manufacturing a semiconductor device, the height of at least one of the external terminals may be lowered to flatten tip surfaces thereof.

A semiconductor device in accordance with the present invention includes: a substrate; a semiconductor chip that is mounted on one surface of the substrate and sealed with resin; and a plurality of external terminals that are provided on another surface of the substrate in multiple rows and multiple columns, and electrically connected to the semiconductor chip. The substrate is warped. Tips of the plurality of the external terminals are disposed on generally the same plane.

In accordance with the present invention, since the tips of the external terminals are disposed on the same plane, the semiconductor device can be mounted even when the substrate is warped.

In the semiconductor device, the substrate may be warped toward the side of a surface thereof on which the semiconductor chip is mounted.

In the semiconductor device, the substrate may be warped toward the side of a surface thereof on which the external terminals are mounted.

A semiconductor device in accordance with the present invention includes: a substrate; a semiconductor chip that is mounted on one surface of the substrate and sealed with resin; and a plurality of external terminals that are provided on another surface of the substrate in multiple rows and multiple columns, and electrically connected to the semiconductor chip. Tip surfaces thereof are flat and side surfaces thereof are curved.

In accordance with the present invention, a semiconductor device that has low external terminals and has a good mountability can be provided.

A circuit substrate in accordance with the present invention is provided with the aforementioned semiconductor device mounted thereon.

An electronic equipment in accordance with the present invention has the semiconductor device described above.

### BRIEF DESCRIPTION OF THE DRAWINGS

FIGS. 1 (A) and 1 (B) are schematics describing a method of manufacturing a semiconductor device in accordance with a first exemplary embodiment of the present invention;

FIGS. 2 (A) and 2 (B) are schematics describing the method of manufacturing a semiconductor device in accordance with the first exemplary embodiment of the present invention;

FIGS. 3 (A) and 3 (B) are schematics describing a method of manufacturing a semiconductor device in accordance with a modified example of the first exemplary embodiment of the present invention;

FIGS. 4 (A) and 4 (B) are schematics describing a method of manufacturing a semiconductor device in accordance with a second exemplary embodiment of the present invention;

FIG. 5 is a schematic that shows a circuit substrate on which a semiconductor device manufactured by the method of manufacturing a semiconductor device in accordance with any one of the exemplary embodiments of the present invention is mounted;

FIG. 6 is a schematic that shows an electronic apparatus having a semiconductor device manufactured by the method of manufacturing a semiconductor device in accordance with any one of the exemplary embodiments of the present invention;

FIG. 7 is a schematic that shows an electronic apparatus having a semiconductor device manufactured by the method of manufacturing a semiconductor device in accordance with any one of the exemplary embodiments of the present invention.

### DETAILED DESCRIPTION OF PREFERRED EMBODIMENTS

Hereunder, exemplary embodiments of the present invention are described with reference to the accompanying drawings. However, the present invention is not limited to the exemplary embodiments described below.

### First Exemplary Embodiment

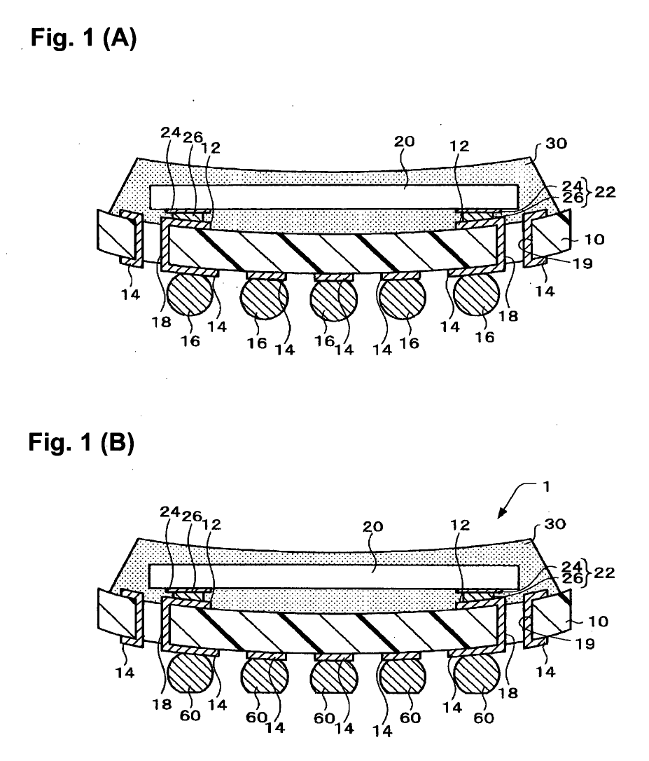

FIGS. 1 (A) and 1 (B) are schematics describing a method of manufacturing a semiconductor device in accordance with a first exemplary embodiment of the present invention.

Initially, a substrate 10 is prepared. The substrate 10 may also be referred to as a wiring substrate or an interposer. The shape of the substrate 10 in the plan view is generally a rectangle, but is not limited to this particular shape. Also, the overall configuration of the substrate 10 is not particularly limited. Further, the thickness of the substrate 10 is not limited.

The material of the substrate 10 may be either organic or inorganic, and may be formed from a compound structure of these materials. As the substrate 10, a substrate or a film composed of, for example, polyethylene terephthalate (designated herein as PET) may be used. Alternatively, a flexible substrate composed of polyimide resin may be used as the substrate 10. A tape that is used in a FPC (Flexible Printed Circuit) technique or a TAB (Tape Automated Bonding) technique may be used as the flexible substrate. Also, as the substrate 10 that is composed of an inorganic material, for example, a ceramics substrate or a glass substrate may be used. As a compound structure of organic and inorganic materials, for example, a glass epoxy substrate may be used. Also, as the substrate 10, a multiple-layer substrate or a build-up type substrate may be used.

The substrate 10 may have wiring patterns 12. The wiring patterns 12 are formed on one surface of the substrate 10. The wiring patterns 12 may be formed from a plurality of layers. For example, any of copper (Cu), chrome (Cr), titanium (Ti), nickel (Ni), and titanium-tungsten (Ti—W) layers may be stacked in layers to form the wiring patterns 12. The wiring patterns 12 may be formed by using a photolithography, sputter, or plating process. Also, a part of the wiring pattern 12 may be formed with a land section (not shown) having an area larger than a portion thereof that becomes to be a wiring. The land section has a function to secure a sufficient electrical connection section, and may often be provided as an electrical connection section for the electrode 22 of the semiconductor chip 20 or for an external terminal 16.

The substrate 10 may be provided with through holes 19 for electrically conducting the two surfaces of the substrate 10. A part of the wiring pattern 12 may have a land section (not shown). By forming the through holes 19, electrical connections to the wiring patterns 12 can be made from either of the surfaces of the substrate 10 regardless of the side of the substrate 10 on which the wiring patterns 12 are formed.

As shown in FIG. 1 (A), the substrate 10 in accordance with the present exemplary embodiment may have wiring patterns 14 on a surface thereof opposite to the surface where the wiring patterns 12 are formed. The wiring patterns 14 may be formed on a surface of the substrate 10 opposite to the side thereof where the semiconductor chip 30 is mounted. In this case, the wiring patterns 12 and the wiring patterns 14 are electrically connected to one another. In the example shown in FIG. 1 (A), through holes 18 are formed in the substrate 10, and the wiring patterns 12 and the wiring patterns 14 are electrically connected by the through holes 18. A dielectric film may be formed on the surfaces of the wiring patterns 14 in areas that avoid portions thereof that contact the external terminals 14.

Next, the semiconductor chip 20 is mounted on the substrate 10. The semiconductor chip 20 may be, for example, a flash memory, SRAM, DRAM, ASIC or MPU. The semiconductor chip 20 may in many cases have a rectangular (square or oblong) configuration in plan view. A passivation film may be formed on the active surface of the semiconductor chip 20. The passivation film may be formed from SiO2, SiN, polyimide resin or the like, for example.

A plurality of electrodes 22 are formed on one surface (active surface) of the semiconductor chip 20. The electrodes 22 may be arranged along at least one side (two parallel sides or four sides in many cases) of the active surface of the semiconductor chip 20. The electrodes 22 may include pads 24 and bumps 26. The pads 24 may be formed thin and flat with aluminum or copper, for example, on the semiconductor chip 20. The bumps 26 may be formed through electroless plating, or may be ball bumps that are formed through wire-bonding. A nickel, chrome or titanium layer may be added between the pads 24 and the bumps 26 as a layer to reduce or prevent diffusion of bump metal. Alternatively, the electrodes 22 may be composed only with pads without the bumps 26.

As shown in FIG. 1 (A), by using the bumps formed at the pads 24, the semiconductor chip 20 may be face-down bonded. In this case, the bumps 26 and the wiring patterns 12 may be bonded together in any of configurations including bonding with conductive resin paste, metal bonding with Au—Au, Au—Su, solder or the like, or bonding by shrinkage force by dielectric resin. The semiconductor device in accordance with the present exemplary embodiment may be a stacked-type semiconductor device in which a plurality of semiconductor chips 20 mounted on the substrate are stacked in layers.

Next, the semiconductor chip 20 is sealed with sealing material (molding resin) 30. As the sealing material 30, a thermosetting resin may often be used, but it is not limited to this particular one. For example, an epoxy resin or the like may be used as the sealing material 30.

As shown in FIG. 1 (A), the substrate 10 in accordance with the present exemplary embodiment is warped toward the side on which the semiconductor chip is mounted, in other words, is warped such that the side thereof on which the semiconductor chip 20 is mounted becomes to be a concave surface. The substrate 10 may be warped by using a difference in the shrinkage force between the substrate 10 and the sealing material 30 in the process of molding and sealing the semiconductor chip 20. For example, in the relation between the sealing material 30 and the substrate 10, when the shrinkage caused by setting of the sealing resin 30 is greater than the shrinkage caused by cooling of the substrate 10, the substrate 10 can be warped by the shrinkage caused by hardening of the sealing resin 30. If the substrate 10 is slightly warped in advance toward the side on which the semiconductor chip 20 is mounted, the substrate 10 would be substantially warped toward the side on which the semiconductor chip 20 is mounted by the shrinkage caused by hardening of the sealing resin 30 (see FIG. 1 (A)).

Next, external terminals 16 are formed on the substrate 10. In the example shown in FIG. 1 (A), the external terminals 16 are formed on the wiring patterns 14, and electrically connected to the wiring patterns 12 through the wiring patterns 14 (and the through holes 18). As the external terminals 16, solder balls or the like may be used. The size of the external terminals 16 is not particularly limited, but the external terminals 16 can be formed by using conductive materials having the same height.

However, the external terminals 16 in accordance with the present exemplary embodiment are not limited to the above, but the external terminals 16 may be provided on the wiring patterns 12 through the through holes 19 that is formed in the substrate 10. More specifically, external terminals 16 are provided on parts (for example, land sections) of the wiring patterns 12 that are exposed through the through holes 19, and may be protruded from a side of the substrate opposite to the side where the semiconductor chip 20 is mounted. The external terminals 16 may be formed from solder; solder that is a material of solder balls may be filled in the through holes 19, and conductive members integral with solder balls may be formed at the through holes 19.

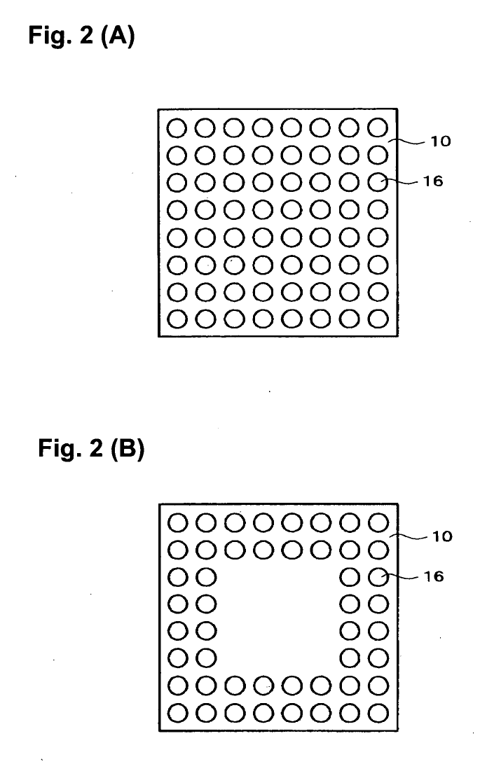

The external terminals 16 can be formed in any configuration including a FAN-IN type shown in FIG. 1 (A), FAN-OUT type, or FAN-IN/OUT type. Also, the external terminals 16 may be disposed in an area array configuration shown in FIG. 2 (A), or may be disposed in end side areas of the substrate 10 in multiple rows and multiple columns while avoiding the center section of the substrate 10, as shown in FIG. 2 (B).

Next, as shown in FIG. 1 (B), the semiconductor device is fabricated by lowering the height of the external terminals 16. More specifically, the tip side of the external terminals 16 may be grounded to lower the height of the external terminals 16. Alternatively, the tips of the external terminals 16 may be fused to lower the height of the external terminals 16. However, the method of manufacturing the semiconductor device in accordance with the present exemplary embodiment is not limited to this example. By the above, a semiconductor device 1 that is low in height and excellent in mountability can be manufactured. In this case, the semiconductor device 1 includes one or a plurality of external terminals 60 whose tip surfaces are flat and side surfaces are curved.

As shown in FIG. 1 (A), the substrate 10 in accordance with the present exemplary embodiment is warped toward the side on which the semiconductor chip 20 is mounted, e.g., is warped such that the side thereof on which the semiconductor chip 20 is mounted becomes to be a concave surface. Consequently, when external terminals 16 having the same height are used, there were occasions where the tips of the external terminals 16 could not be arranged on a plane surface to a degree that they are mountable on a mounting substrate. However, even in this case, by lowering the height of any one (or a plurality) of the plural external terminals 16, the tips of the external terminals 60 can be disposed on generally the same plane, to a degree that they are mountable (see FIG. 1 (B)). For this reason, as shown in FIG. 1 (A), even when the substrate 10 is warped, a semiconductor device 1 that is mountable can be manufactured.

Also, when the substrate 10 is warped toward the side on which the semiconductor chip 20 is mounted, e.g., is warped such that the side thereof on which the semiconductor chip 20 is mounted becomes to be a concave surface, as shown in FIG. 1 (A), the height of the external terminals 16 can be lowered in a manner that the height of the external terminals 60 toward the end sections of the substrate 10 can be made greater than the height of the external terminals 60 in the center section side of the substrate 10. For this reason, the volume of the external terminal 60 that is formed on the end side of the substrate 10 becomes greater than the volume of the external terminal 60 formed adjacent to the center section side of the substrate 10 (see FIG. 1 (B)). By this, the bonding force adjacent to the end section of the semiconductor device where stresses are likely to concentrate can be made greater, and thus the semiconductor device 1 that is highly reliable against stresses can be manufactured.

### Modified Example

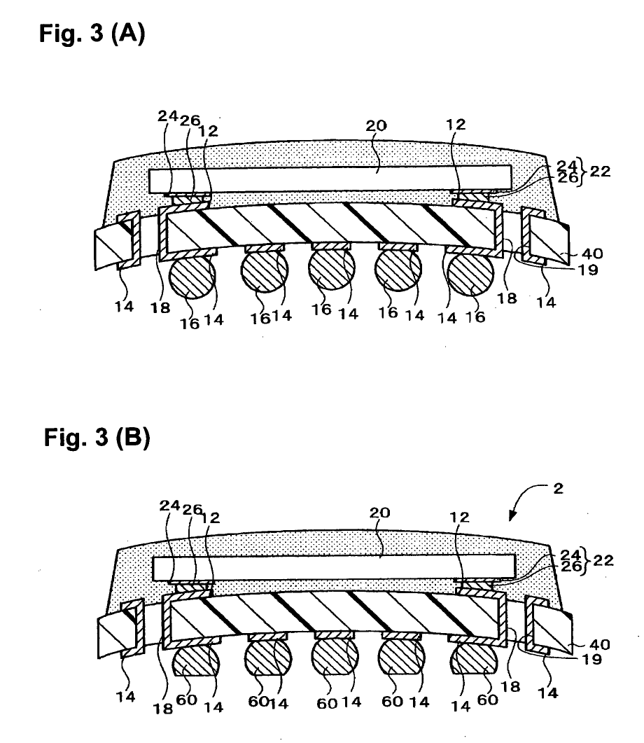

FIGS. 3 (A) and 3 (B) are schematics describing a method of manufacturing a semiconductor device in accordance with a modified example of the first exemplary embodiment of the present invention.

A semiconductor device in accordance with the present exemplary embodiment has a substrate 40. As shown in FIG. 3 (A), the substrate 40 is warped toward the side thereof on which external terminals 16 are formed, e.g., is warped such that the side thereof on which the external terminals 16 are formed becomes to be a concave surface. The substrate 40 may be warped by using a difference in the shrinkage force between the substrate 40 and the sealing material 30 in the process of molding and sealing the semiconductor chip 20. For example, in the relation between the sealing material 30 and the substrate 40, when the shrinkage caused by setting of the sealing resin 30 is greater than the shrinkage caused by cooling of the substrate 40, the substrate 40 can be warped by the shrinkage caused by hardening of the sealing resin 30. If the substrate 40 is slightly warped in advance toward the side on which the external terminals 16 are formed, the substrate 40 would be substantially warped toward the side on which the external terminals 16 are formed by the shrinkage caused by hardening of the sealing resin 30 (see FIG. 3 (A)).

In the present exemplary embodiment, the same contents described in the first exemplary embodiment are applicable with respect to the method of forming wiring patterns 12 and 14, the method of mounting the semiconductor chip 20, and the arrangement of the external terminals 16 (see FIGS. 2 (A) and 2 (B)).

Then, the height of the external terminals 16 is lowered to manufacture a semiconductor device 2 shown in FIG. 3 (B). The substrate 40 in accordance with the present exemplary embodiment is warped toward the side thereof on which external terminals 16 are formed, e.g., is warped such that the side thereof on which the external terminals 16 are formed becomes to be a concave surface. Consequently, when external terminals 16 having the same height are used, there were occasions where the tips of the external terminals 16 could not be arranged on a plane surface to a degree that they are mountable on a mounting substrate (see FIG. 3 (A)). However, even in this case, by lowering the height of any one (or a plurality) of the plural external terminals 16, the tips of the external terminals 60 can be disposed on generally the same plane, to a degree that they are mountable (see FIG. 3 (B)). For this reason, as shown in FIG. 3 (A), even when the substrate 40 is warped, the semiconductor device 2 that is mountable can be manufactured. In this case, the semiconductor device 2 includes one or a plurality of external terminals 60 whose tip surfaces are flat and side surfaces are curved. The height of the external terminals 60 that are formed on the end side of the substrate 40 becomes greater than the height of the external terminals 60 that are formed on the center section side of the substrate 40.

### Second Exemplary Embodiment

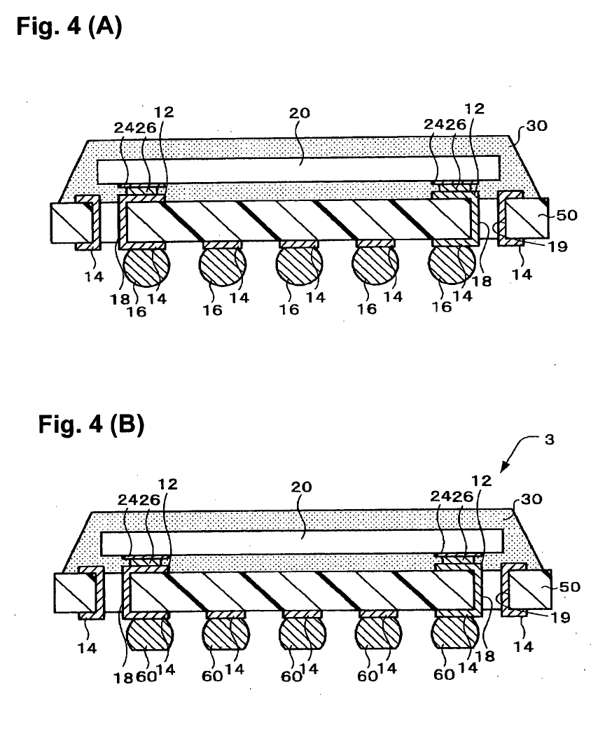

FIGS. 4 (A) and 4 (B) are schematics describing a method of manufacturing a semiconductor device in accordance with a second exemplary embodiment of the present invention. The contents described in the first exemplary embodiment can be applied to the present exemplary embodiment as much as possible.

As shown in FIG. 4 (A), a substrate 50 in accordance with the present exemplary embodiment is flat. In the present exemplary embodiment, the same contents described in the first exemplary embodiment are applicable with respect to the method of forming wiring patterns 12 and 14, the method of mounting a semiconductor chip 20, and the arrangement of the external terminals 16 (see FIGS. 4 (A) and 4 (B)).

Then, the height of the external terminals 16 is lowered to manufacture a semiconductor device. By this, a semiconductor device 3 that is low in height and excellent in mountability can be manufactured. In this case, the semiconductor device 3 has flat tip surfaces and curved side surfaces, and one or a plurality of external terminals 60.

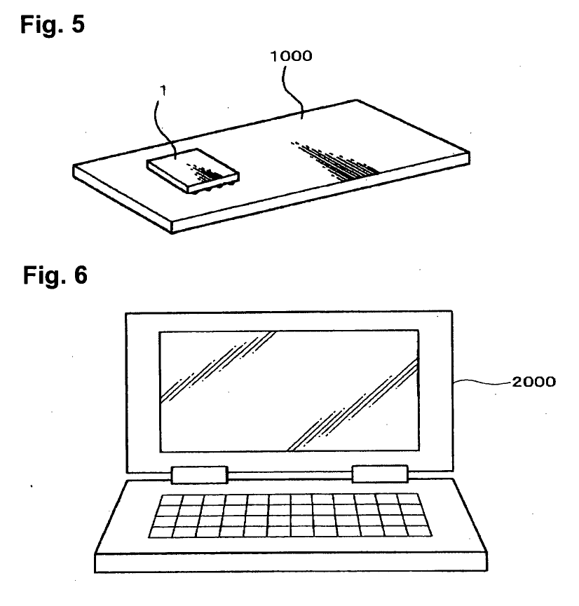

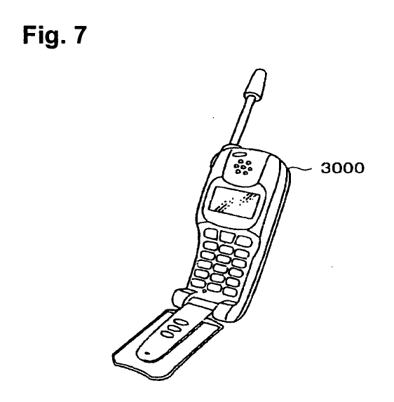

FIG. 5 shows a circuit substrate 1000 on which the semiconductor device 1 in accordance with the exemplary embodiment described above is mounted. Also, as electronic apparatuses having the semiconductor devices in accordance with the exemplary embodiment of the present invention, a notebook type personal computer 2000 is shown in FIG. 6, and a portable telephone 3000 is shown in FIG. 7.

The present invention is not limited to the exemplary embodiments described above, and many modifications can be made. For example, the present invention may include compositions that are substantially the same as the compositions described in the exemplary embodiments (for example, a composition that has the same functions, the same methods and the results, or a composition that has the same objects and results). Also, the present invention includes compositions in which portions not essential in the compositions described in the exemplary embodiments are replaced with others. Also, the present invention includes compositions that achieve the same functions and effects or achieve the same objects of those of the compositions described in the exemplary embodiments. Furthermore, the present invention includes compositions that include related art, later developed or publicly known technology added to the compositions described in the exemplary embodiments.

What is claimed is:

1. A method of manufacturing a semiconductor device, comprising:
lowering a height of at least one of a plurality of external terminals that are electrically connected to a semiconductor chip mounted on one surface of a substrate and sealed with resin, and that are provided on another surface of the substrate in plural rows and plural columns.

2. The method of manufacturing a semiconductor device according to claim 1, further including grinding a tip of the at least one of the external terminals to lower the height.

3. The method of manufacturing a semiconductor device according to claim 1, further including lowering the height of the at least one of the external terminals such that tips of the plurality of external terminals are disposed in generally the same plane.

4. The method of manufacturing a semiconductor device according to claim 1, further including warping the substrate toward the side of a surface thereof on which the semiconductor chip is mounted.

5. The method of manufacturing a semiconductor device according to claim 1, further including warping the substrate toward the side of a surface thereof on which the external terminals are formed.

6. The method of manufacturing a semiconductor device according to claim 1, further including disposing the external terminals in an area array configuration.

7. The method of manufacturing a semiconductor device according to claim 1, further including, after forming the plurality of external terminals to the same height, lowering the height of at least one of the external terminals.

8. The method of manufacturing a semiconductor device according to claim 7, further including lowering the height of at least one of the external terminals to flatten tip surfaces thereof.

9. A semiconductor device, comprising:
a substrate, the substrate being warped;
a semiconductor chip mounted on one surface of the substrate and sealed with resin; and
a plurality of external terminals provided on another surface of the substrate in multiple rows and multiple columns, and electrically connected to the semiconductor chip, the plurality of the external terminals including tips that are disposed on generally the same plane.

10. The semiconductor device according to claim 9, the substrate being warped toward the side of a surface of the substrate on which the semiconductor chip is mounted.

11. The semiconductor device according to claim 9, the substrate being warped toward the side of a surface of the substrate on which the external terminals are mounted.

12. A semiconductor device, comprising:
a substrate;
a semiconductor chip mounted on one surface of the substrate and sealed with resin; and
a plurality of external terminals provided on another surface of the substrate in multiple rows and multiple columns, and electrically connected to the semiconductor chip, the plurality of external electrodes including tip surfaces that are flat and side surfaces that are curved.

13. A circuit substrate assembly, comprising:
a circuit substrate; and
the semiconductor device according to claim 9 mounted on the circuit substrate.

14. An electronic equipment, comprising:
the semiconductor device according to claim 9.
